(19) United States
(12) Patent Application Publication
(10) Pub. No.: US 2017/0025853 A1
(43) Pub. Date: Jan. 26, 2017

(54) THÉVENIN EQUIVALENT BASED STATIC CONTINGENCY ASSESSMENT

(71) Applicant: Danmarks Tekniske Universitet, Kgs. Lyngby (DK)

(72) Inventors: Hjörtur JÓHANSSON, Reykjavik (IS); Jakob Glarbo MØLLER, Copenhagen S (DK)

(21) Appl. No.: 15/301,695

(22) PCT Filed: Apr. 7, 2015
(86) PCT No.: PCT/EP2015/057525

§ 371 Date: Oct. 3, 2016

(30) Foreign Application Priority Data
Apr. 4, 2014 (EP) 14163623.3

(51) Int. Cl. H02J 3/04; G05F 1/66; G01R 25/00; H02J 13/00

(52) U.S. Cl. CPC H02J 3/04; H02J 13/0017; G05F 1/66; G01R 25/00; H02J 2003/001

(57) ABSTRACT

The present invention relates to a method for static security assessment of a power system and a real time static security assessment system for assessing a power system, the power system having a plurality of generators, the plurality of generators being represented in the network by a plurality of voltage controlled nodes, wherein the method for static security assessment of the power system comprises receiving information of a present state of the power system, determining a Thevenin equivalent for each voltage controlled node, determining for each voltage controlled node on basis of the determined present state of the power system and determining a first representation of the network based on the determined Thevenin equivalents, determining a modified representation of the network, wherein the modified representation is a representation of the network having at least one contingency, wherein at least one Thevenin equivalent of at least one voltage controlled node is modified due to the at least one contingency, the modified network representation being determined on the basis of the modified Thevenin equivalents, calculating voltage angles of the modified Thevenin equivalents, and evaluating the voltage angles to determine whether the network having at least one contingency admit a steady state. Also a method of providing information on a real time static security assessment of a power system is disclosed.

### FIELD OF INVENTION

The present invention relates to power systems, and in particular to methods of and systems for security assessment of power systems, especially to such systems and methods for static security assessment of power systems, such as for contingency analysis in static security assessment of a power system, such as for real-time assessment of power systems and to real-time security warning systems for assessing a power system. More particularly, the invention relates to methods of and power systems for Thévenin equivalent based static contingency assessment of power systems.

### BACKGROUND

In recent years, there has been a tendency towards power systems having more and smaller energy sources providing input to the power networks. The focus on climate change and the consequential focus on reduction of CO₂ emissions lead away from large coal fired power generators providing a significant share of the total input to the power system, and towards power systems where the share of power from renewable energy sources, such as power from wind, water or solar energy sources, is significantly higher than hitherto. However, renewable energy sources are relatively uncontrollable and typically each renewable energy source is relatively small and they are typically spread over a wide area in the power system.

The existing transmission systems are not necessarily designed to handle these new production patterns, and traditional approaches where security assessment has been carried out off-line by system planners are insufficient in today's complex networks, which was seen e.g. from the major blackouts in electric power systems in Sweden and Denmark in September, 2003 and in North-Eastern and Mid-Western United States and parts of Canada in August 2003, each affecting millions of people.

Thus, because of the limited predictability of the renewable energy sources, the productions patterns may change more rapidly than before and, hence, the slow off-line calculation and/or analysis are no longer sufficient.

In response to these new production patterns, sophisticated computer tools have been developed for power system analysis and led e.g. to the use of Phasor Measurement Units (PMU's) that provide synchronized measurements in real time, of voltage and current phasors along with frequency measurements. The introduction of PMUs together with advances in computational facilities and communications, opened up for new tools for controlling, protecting, detecting and monitoring of the power systems.

Assessment of power systems using PMU's is known, and it is known to determine an effect of a suggested countermeasure to mitigate aperiodic small-signal instability in a power system. For example, an analysis may be performed in a situation in which the power system has already been subject to an event which has compromised system security, for example using time domain simulations, and the effect of various possible counter measures is analysed. The counter measures may for example include an adjustment of loads which is made to bring the system back to a secure state after being subjected to the event. In such cases, it is assumed that a steady state does exist and the Thévenin equivalent representation is applied for determining only the voltage angles at voltage controlled nodes following the activation of a certain counter measure in the power system, see for example Dimitrova et al. “Fast Assessment of the Effect of Preventive Wide Area Emergency Control”, IEEE PES ISGT Europe 2013 IEEE. 6 Oct. 2013, pages 1-5. Contingency analyses are the processes of evaluating the influences of topological changes to a power system and are typically carried out for power systems to ensure that overloading of a power system does not occur even under any likely contingency so that the power systems may maintain system security. A number of simulators are known which may test contingencies, and for example test the severity of a predefined set of disturbances in order to operate the system defensively.

Often, time domain simulations or power flow methods are used for contingency assessment, and for example methods based on Newton-Raphson's power flow method are widely used.

However, often time domain simulations are not the best suited methods for real-time or online monitoring, and the power flow methods have been seen to be not providing entirely reliable results.

### SUMMARY

It is therefore an object of the present invention to provide an improved method and system for static security assessment of a power system.

According to the present invention, the above and other objects are provided by a method for conducting contingency analyses in static security assessment of a power system and/or for static security assessment of a power system. The power system has a plurality of generators injecting power into a network having a plurality of nodes and a plurality of branches, the plurality of generators being represented in the network by a plurality of voltage controlled nodes. The method comprises receiving information of a present state of the power system, determining a Thévenin equivalent for each voltage controlled node, wherein a Thévenin equivalent is determined for each voltage controlled node on basis of the determined present state of the power system and determining a first representation of the network based on the determined Thévenin equivalents. The method may further comprise applying at least one contingency to the network. The method further comprises determining a modified representation of the network, wherein the modified network representation is a representation of the network having at least one contingency, such as at least one applied contingency, wherein at least one Thévenin equivalent of at least one voltage controlled node is modified due to the at least one contingency, such as the at least one applied contingency, the modified network representation being determined on the basis of the modified Thévenin equivalents. The method may further comprise calculating voltage angles of the modified Thévenin equivalents, and evaluating the voltage angles to determine whether the network having at least one contingency, such as at least one applied contingency admits a steady state. Typically, the voltage angles of the modified Thévenin equivalents are calculated for both voltage controlled nodes and for nodes which are without voltage control.

According to another aspect of the present invention, a real-time security warning system for assessing a power system or for conducting contingency analyses in a power system is provided, the power system having a plurality of generators injecting power into a network having a plurality of nodes and a plurality of branches. The plurality of generators may be represented in the network by a plurality of voltage controlled nodes, such as a plurality of nodes of power injection. The system comprises a data processing means configured for receive information of a present state of the power system, determining a Thévenin equivalent for each voltage controlled node, wherein a Thévenin equivalent is determined for each voltage controlled node on basis of the determined present state of the power system and determining a first representation of the network based on the determined Thévenin equivalents. The method may further comprise applying at least one contingency to the network. The data processing means may further be configured to determine a modified representation of the network, wherein the modified network representation is a representation of the network having at least one contingency, such as at least one applied contingency, wherein at least one Thévenin equivalent of at least one voltage controlled node is modified due to the at least one contingency, such as the at least one applied contingency, the modified network representation being determined on the basis of the modified Thévenin equivalents. The data processing means may further be configured to calculate voltage angles of the modified Thévenin equivalents, and evaluating the voltage angles to determine whether the network having at least one contingency, such as at least one applied contingency, admits a steady state. Typically, the voltage angles of the modified Thévenin equivalents are calculated for both voltage controlled nodes and for nodes which are without voltage control.

According to a still further aspect of the present invention also a computer program comprising program code means for performing the method(s) as herein described when said computer program is run on a computer is provided, and, furthermore, a computer readable medium having stored thereon program code means for performing the method(s) as herein described when said program code means is run on a computer is provided.

According to another aspect of the present invention, a method of providing information on a real time static security assessment of a power system is provided, such as a method of providing information on a contingency analysis conducted in static security assessment of a power system. The power system has a plurality of generators injecting power into a network having a plurality of nodes and a plurality of branches, the plurality of generators being represented in the network by a plurality of nodes of power injection. The method comprises receiving information of a present state of the power system, determining a two source Thévenin equivalent representation, where the representation includes the power system as seen from each voltage controlled node, wherein a Thévenin equivalent is determined for each voltage controlled node on basis of the determined present state of the power system, and wherein the Thévenin equivalent comprises a Thévenin voltage and a Thévenin impedance. A representation of the network based on the determined Thévenin equivalents may be determined, and furthermore, at least one contingency may be applied to the network. The method may further comprise determining a modified representation of the network representation, wherein the modified network representation of the network having at least one contingency, such as at least one applied contingency may be determined, wherein at least one Thévenin equivalent of at least one voltage controlled node is modified due to the at least one contingency, such as the at least one applied contingency, the modified network representation being determined on the basis of the modified Thévenin equivalents. The method further comprises calculating voltage angles of the modified Thévenin equivalents, evaluating the voltage angle to determine whether the modified network representation of the network having at least one applied contingency admits a steady state, and outputting information on static security assessment of the modified network representation of the network, wherein the information comprises the evaluated voltage angles. Typically, the voltage angles of the modified Thévenin equivalents are calculated and evaluated for both voltage controlled nodes and for nodes which are without voltage control.

The a real-time security warning system may further comprise an interface means for outputting information on the static security assessment of the modified network representation of the network, wherein the information comprises the evaluated voltage angle.

It is an advantage of the present invention that the method may perform a static security assessment and/or conducting contingency analyses in static security assessment of a power system efficiently and fast, since the processing of determining a modified representation of the network may be performed in parallel for each voltage controlled node in the network. Furthermore, the evaluation of the voltage angles for the respective voltage controlled nodes may be performed in parallel, and thereby, the rate at which the static security assessment of the power system may be performed may be further improved.

It is a further advantage of the present invention that the method provides a more precise and reliable static security assessment and/or contingency analysis in static security assessment of the power system since the assessment is provided by a method which does not include a slack variable or any initial estimated values or guesses.

It is another advantage of the present invention that the method may determine an ideal condition for providing a deterministic representation of the power system conditions by determining whether the voltage controlled nodes of a power system admits a steady state.

Thévenin equivalent may comprise a Thévenin voltage, a Thévenin current, a Thévenin voltage angle and a Thévenin impedance configured to a representation of a network seen from a voltage controlled node.

A contingency may be a topological change to the network or a disturbance, such as a broken transmission line grid, a loss of a single transmission line, a loss of a generator, a damaged generator and/or any fault that provide a fault to the power system that may result in an unstable power system.

A network/power system may admit a steady state operating mode, or be in a steady state operating mode, when no transients or few and diminishing transients from other disturbances may be present, or when it for example is determined that the transients are attenuating. Thus, the network admits a steady state when the evaluation of at least the voltage angles shows that the network at least converges towards a steady state. The network may be determined to admit a steady state when a stability criterion is satisfied, such as for example a voltage angle stability criterion.

It is an advantage of the present disclosure that it may be determined whether a network admits a steady state or not after a contingency, such as a topological contingency has been applied to the network.

It is a further advantage of the present disclosure that by determining a modified network representation immediately after a contingency, such as a topological contingency, has been applied to the network, the modified network representation being determined on the basis of modified Thévenin equivalents, provides a computed or calculated modified network representation, which provides a true representation of the modified network compared to a time domain simulation in which the presence of a steady state is a pre-requisite for the simulation to provide a result.

The power system may be any power system having a number of generators interconnected via a number of branches in a transmission line grid. Typically, the power system will have a plurality of nodes or busses, a plurality of branches and a plurality of generators. The nodes may be nodes interconnecting branches.

Information about a current or present state of the power system may be received. The information may be obtained from another system or the information about the present state may be obtained by performing measurements on the system. The information may be obtained by measuring voltages and/or currents at a number of nodes in the system. Preferably, voltage and current phasors at a number of nodes are determined by measurement, and alternatively or additionally, also the frequency may be determined by measurement at a number of nodes. In some embodiments, the measurements are performed in real-time, and preferably the measurements across the power system are time synchronized, such as time synchronized via a GPS signal. The measurements provide information about a current state of the system and this information may be retrieved for use with the present invention. In some embodiments, the method may be performed on-line. The present state of the system may be obtained by wide area measurements.

Thus, the present invention may provide an on-line or a real-time static security assessment of the power system and receive the information in real-time or on-line.

The measurements may be performed in real time, and may thus, the measurements may be provided within a time frame in the order of milliseconds or microseconds. Typically, the present state of the power system may be determined sequentially, such as every 20 ms, every 40 ms, every 100 ms, every second, every minute, every 5 minutes, every 15 minutes, etc. For each or for a predetermined fraction of the sequential determinations of a present state of the power system, a representation of the network may be obtained, and thus system Thévenin impedances and a representation of the network may be obtained for each voltage controlled node, or generator. Thereby, the assessment may be performed in real-time. Thus, in some embodiments, the Thévenin equivalents, the modified Thévenin equivalents and/or the voltage angles may be determined in real-time. The system and the methods may for example be able to analyse at least 1000 contingencies every 3 minutes, such as 1000 contingencies every one minute, such as 10000 contingencies every minute.

One preferred method of determining the present state of a power system is by using Phasor Measurement Unit measurements. A phasor measurement unit (PMU) is a device that provides synchronized measurements, in real-time, of voltage and current phasors along with a measurement of frequency, thus the PMU measurements may comprises measurements of voltage and current phasors. Synchronism between the individual PMUs may be achieved by the use of a common synchronizing signal from GPS satellites. The synchronization of the sampling process for different waveforms, measured at locations that may be hundreds of kilometres apart, enables the use of the phasors on the same phasor diagram and thus the use of these directly for circuit analysis of the system. The PMUs may be installed in substations or nodes dispersed over a wide area in a power system, and may receive a GPS signal for ensuring synchronisation of the measured values so that the sampled voltage or current waveform may be used to derive the phasor values which may then be plotted in a same complex plane for the purpose of analysis. The advantage of using the PMUs is that the PMUs provide high accuracy, and in that they are widely installed in power systems, they may provide a full observability of the system operating conditions in real-time, and furthermore provide a high repetition rate, such as once per cycle of the system frequency, for the measurements. In that a full observability of the power system is obtained, a further step of estimating unobserved system variables may not be necessary. The PMUs, thus, may provide for a synchronized snapshot of the system conditions in real time. To provide full observability, enough measurements should be determined so as to provide a unique representation of the power system.

Preferably, the measurements from the PMUs are provided to a phasor data concentrator, for correlating the data and feeding of the data to applications, such as the present application.

The step of determining a present state of the power system may thus comprise obtaining synchronized Phasor Measurement Unit measurements from a plurality of nodes of the power system.

The network may have a plurality of nodes and a plurality of branches, and the plurality of generators may be represented in the network by a plurality of voltage controlled nodes.

Each generator may be a synchronous machine and each generator may comprise a number of synchronous machines operating e.g. in parallel. In some embodiments, the generator is a multiple phase generator, typically such as a three phase generator.

In a stable steady state mode, the generator is typically capable of generating sufficient synchronizing torque so that operation at a stable equilibrium point may be maintained. A lack of sufficient steady state synchronizing torque may cause aperiodic increase in rotor angle and a loss of synchronism. In steady state, the power injection from a voltage controlled node may be at least equal to the mechanical power Pₘ. Thus, when it is determined that the network admits a steady state, it is determined that the generator, given the calculated voltage angles, will be capable of generating sufficient synchronizing torque.

To determine a representation of the network, a Thévenin equivalent may be determined for each voltage controlled node on basis of the determined present state of the power system. The representation of the network may be based on a two-source Thévenin equivalent, wherein the two-source Thévenin equivalent comprises the determined Thévenin equivalent and a voltage phasor of the voltage controlled node. Thus, each voltage controlled node is represented by both the voltage phasor of the voltage controlled node, and the Thévenin equivalent as seen from the voltage controlled node and into the power system.

At least one contingency may be applied to the network, and it may be evaluated whether the application of the contingency results in a stable network condition. Thus, a representation of a network in a pre-fault condition is determined, a contingency or fault is applied, and using simulations, a representation of a network in a post-fault condition is determined.

The at least one contingency may be a topological contingency and may be at least one broken transmission line grid, loss of at least one single transmission line, loss of at least one generator, at least one damaged generator and/or at least any fault that results in an unstable power system.

The representation of the network seen from a voltage controlled node may be in a stable network condition when an injected power at the voltage controlled node is at least equal to a mechanical input power to a rotor shaft configured to the voltage controlled node. Thereby, the network may be in a stable condition when the power going into the generator is less than the power going out from the generator and into a voltage controlled node. Alternatively, the network may be in a stable condition when the power going into the generator is less than the largest possible amount of power which the power system can absorb from that generator.

In one or more embodiments, at least voltages at non-controlled nodes and voltages at voltage controlled nodes may be compared against operational limits. Non-controlled nodes may for example be loads and may consume power generated by the voltage controlled nodes. It is an advantage of comparing voltages against operational limits since any violation of operational limits may be avoided. Furthermore, also voltage angles may be compared against operational limits.

An example of operational limits used in static security assessment of power systems may be found in the Union for the Coordination of the Transmission (UCTE (2004)). The operational limits may be, e.g. a permanent admissible transmission loading (PATL), a temporary admissible transmission loading (TATL), a Tripping current (TC), a Normal voltage range, an Exceptional voltage range, a rotor angle stability limits, etc.

In some embodiments, a calculation of the Thévenin equivalent for each voltage controlled node is performed assuming a constant active power injection and constant voltage magnitudes for each voltage controlled node. In that the generators may be represented by power injections at nodes of constant steady state voltage magnitude, the degrees of freedom are reduced.

In one or more embodiments, a grid transformation matrix may comprise calculated Thévenin voltages for each voltage controlled node, one or more corresponding grid transformation coefficients and one or more corresponding voltages of voltage controlled nodes.

The grid transformation coefficient may be a relation between the Thévenin equivalent voltage at a voltage controlled node and voltage phasors at neighbouring voltage controlled nodes.

Alternatively, the grid transformation coefficient may be a relation between the Thévenin equivalent voltage at a voltage controlled node and voltage phasors at any voltage controlled nodes.

In some embodiments, it may be presupposed that each voltage controlled node is primarily influenced by neighbouring voltage controlled nodes, such as by first degree neighbouring voltage controlled nodes, or second degree neighbouring voltage controlled nodes. Hereby, for each voltage controlled node, a limited network, i.e. a secondary network needs to be evaluated. Hereby, a less complex representation of the power system is achieved and thus may allow for a faster computation. It is an advantage of representing the network using a secondary network for each voltage controlled node in that the analysis may then be performed using parallel computing.

In some embodiments, at least a part of the modified network representation corresponds to a corresponding part of the first network representation. The determined Thévenin equivalents on which the first network representation is based may correspond to Thévenin equivalents on which the modified network representation is based in at least the part of the modified network representation corresponding to a part of the first network representation.

Thus, depending on the contingency or perturbation applied to the network a smaller or larger part of the network may be affected. Hereby, only those voltage controlled nodes which are affected by a given perturbation or contingency needs to be re-evaluated to determine whether the system admits a steady state or stable network condition.

The method and system are provided to enable a static security assessment of the system and/or to conduct contingency analyses in a static security assessment. It is known that when a contingency is applied to a power system, typically, a transient behaviour will be seen, and thus, the voltage angles may in some embodiments be evaluated when these transients have faded out and the power system is in a static mode.

The Thévenin equivalent comprises a Thévenin voltage and a Thévenin impedance. In order to ensure that the system admits a steady state before a decision is taken as to whether the system is in a stable or unstable condition, an iterative process of determining the voltage angles may be applied. The determined Thévenin voltages may be re-calculated based on the calculated voltage angles of the modified Thévenin equivalents, and modified voltage angles may be calculated on basis of the updated Thévenin voltages and a change in voltage angle may be evaluated.

The change in voltage angle may be performed by comparing the modified voltage angle to the calculated voltage angle, and the re-calculation of the voltage angles and the Thévenin equivalents, being dependent on each other, the iterative re-calculation is repeated until a convergence criterion is satisfied, such as when the change in voltage angle is below a predetermined voltage angle change threshold. The voltage angle may be determined for voltage controlled nodes and/or for non-voltage controlled nodes.

The data processing means may be any processing means configured to handle the received information and the processing of the received information. In some embodiments, the data processing means may comprise processors configured for parallel processing.

The methods and systems as herein disclosed may be used for evaluation of power flow in a network, and the methods and systems as herein disclosed may be used for testing an operational security criterion.

### BRIEF DESCRIPTION OF THE DRAWING

FIGS. 1a-c shows an overview of a power system and corresponding measurements; FIG. 1a shows an electric power system, FIG. 1b shows synchronized measurements from two nodes of the electric power system, and FIG. 1c shows the resulting phasors in an impedance plane,

FIG. 2 shows a generalized electric power system, where system loads are represented as impedances and the generators are assumed to maintain constant terminal voltage,

FIG. 3 is a flow chart of a method according to the present invention,

FIG. 4 illustrates a two source Thévenin equivalent representation,

FIG. 5 shows an active power balance for a synchronous generator,

FIGS. 6a-b show schematically power networks comprising a plurality of voltage controlled nodes and non-controlled nodes,

FIG. 7a shows a representation of a network having coupled two source Thévenin equivalent representation, and FIG. 7b shows a grid transformation matrix obtained from the representation of the network in FIG. 7a,

FIG. 8 is a flow chart of a method of providing information on a real time static security assessment of a power system.

FIG. 9 is a flow chart illustrating a method of real time static security assessment,

FIG. 10 shows a simulation result of a method according to the present invention and of Newton Raphson's power flow method,

FIG. 11 shows simulation results of a further embodiment of the method according to the present invention,

FIGS. 12A and 12B show a Nordic 32 test system and simulation results of a method according to the present invention, respectively.

### DETAILED DESCRIPTION OF THE DRAWING

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout. Like elements will, thus, not be described in detail with respect to the description of each figure.

In the present description the term “secondary network” and “a part of a network” may in the following be used to indicate a part of the network being evaluated isolated from the rest of the network.

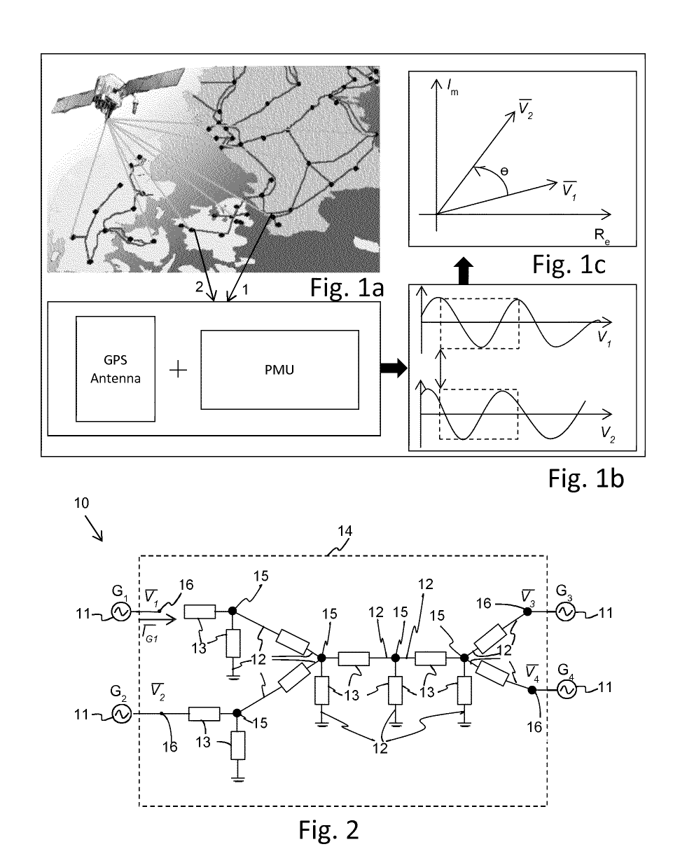

FIG. 1a shows a power system 1, where a Phasor Measurement Unit (PMU), or another measurement device that provide synchronized measurements in real time, of voltage and current phasors along with frequency measurements, is installed at node 1 and node 2. The synchronized measurements are shown in FIG. 1b, for node 1 and node 2, respectively.

FIG. 1c shows the resulting phasors and plotted in the same complex plane. The phase difference θ between the signals from node 1 and node 2, respectively, is indicated.

An exemplary power system 10 is shown in FIG. 2. FIG. 2 shows the power system 10 where all loads are represented as constant impedances 13 and where all generators 11 are assumed to maintain a constant terminal voltage. With all system impedances 13 known, the system operating conditions can be determined from the generators 11 terminal voltages. The power system 10 comprises the generators 11 and the network 14. In the network 14, the generators are represented by a plurality of voltage controlled nodes, or nodes of power injection, 16. Non-controlled nodes 15 and the impedances 13 are interconnected via branches 12. The generators are in FIG. 2 assumed to maintain a constant terminal voltage. In the following this generalized notation will be referred to when discussing the network further.

The Thévenin impedance seen from a given voltage controlled node is the impedance which can be measured if all other voltage controlled nodes were to be short circuited.

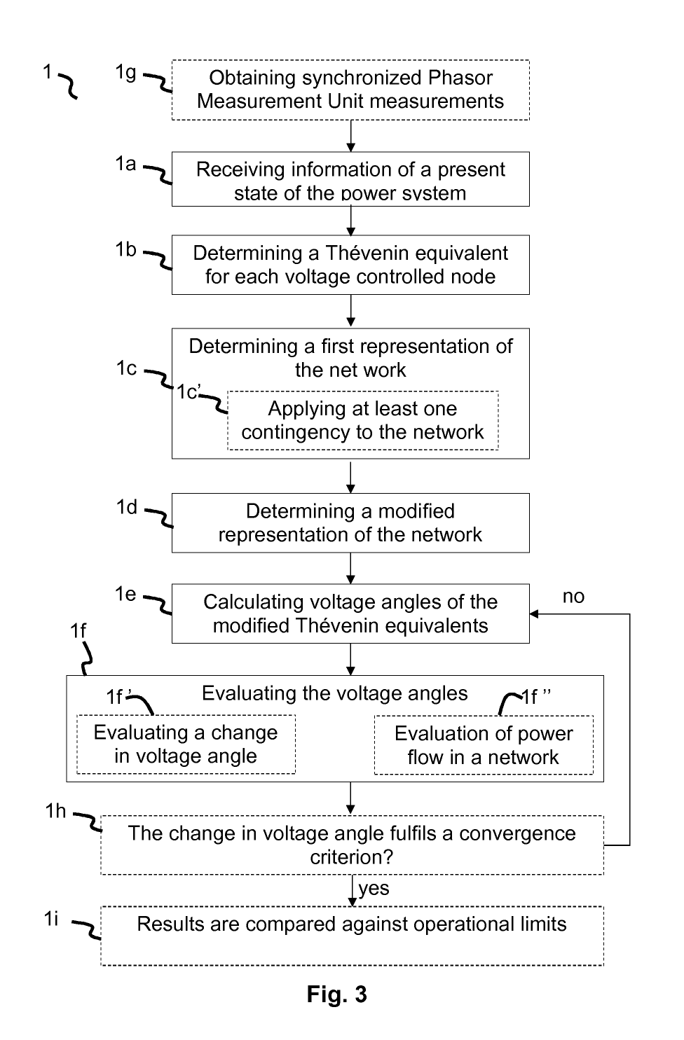

FIG. 3 is a flow chart of a method 1 for static security assessment of a power system 10, such as for a contingency analysis in a static security assessment of a power system. The power system having a plurality of generators 11 injecting power \vec{S}ⱼ into a network 14 having a plurality of nodes (15, 16) and a plurality of branches 12. The plurality of generators 11 are represented in the network 14 by a plurality of voltage controlled nodes 16.

In step 1a, information of a present state of the power system is received, and in step 1b, a Thévenin equivalent for each voltage controlled node 16 is determined, wherein a Thévenin equivalent is determined for each voltage controlled node 16 on basis of the determined present state of the power system 10.

In step 1c, a first representation of the network 14 based on the determined Thévenin equivalents is determined, and in step 1d, a modified representation of the network 14 is determined, wherein the modified representation is a representation of the network 14 having at least one contingency, wherein at least one Thévenin equivalent of at least one voltage controlled node 16 is modified due to the at least one contingency. The modified network representation may be determined on the basis of the modified Thévenin equivalents.

In step 1e, voltage angles δⱼ₀ of the modified Thévenin equivalents are calculated, and in step 1f, the voltage angles δⱼ₀ are evaluated to determine whether the network 14 having at least one contingency is in steady state. The evaluation may be performed using any PMU based evaluation methods. The voltage angels δⱼ₀ of the modified Thévenin equivalents may be calculated for voltage controlled nodes and/or for non-controlled nodes.

The method may optionally comprise the step 1g, in which synchronized Phasor Measurement Unit measurements are initially obtained from a plurality of nodes 15, 16 of the power system 10.

In an exemplary method, at least one contingency may be applied to the network 14 in step 1c′, before the voltage angles δⱼ₀ are evaluated in step 1f to determine whether the application of the contingency results in a stable network condition, thus to evaluate whether the network admits a steady state.

The method may comprise the optional steps 1h and 1i.

Thus, in a further exemplary method, in step 1h, a change in voltage angle Δδ is evaluated by comparing a recalculated modified voltage angle δⱼ₁ to the calculated voltage angle δⱼ₀, and wherein the step of recalculation is repeated until the change in voltage angle fulfils a convergence criterion, for example until the change in voltage angle is below a predetermined voltage angle change threshold.

In another exemplary method, the voltages at non-controlled nodes 15 may be obtained, for example using a linear model.

In step 1i, the resulting post-contingency voltages may be evaluated compared against operational limits of the network or power system.

Additionally, in an exemplary method, in 1f′, the Thévenin equivalent comprises a Thévenin voltage \tilde{E}ₜₕ and a Thévenin impedance Zₜₕ, and wherein determined Thévenin voltages \tilde{E}ₜₕ are re-calculated based on the calculated voltage angles δⱼ₀, of the modified Thévenin equivalents, and re-calculated modified voltage angles δⱼ₁, are calculated on basis of the re-calculated Thévenin voltages and wherein a change in voltage angle is evaluated.

The method is provided to enable a static security assessment of the system, such as to conduct a contingency analysis in static security assessment of the system. It is known that when a contingency is applied to a power system, typically, a transient behaviour will be seen, and thus, the voltage angles may in some embodiments be evaluated when these transients have faded out and the power system is, or is assumed to be, in a static mode.

To determine when the power system is in a static mode an iterative re-calculation of voltage angles is subject to a convergence criterion. Such convergence criterion can be based on the size of change of voltage angles from one iteration to the next.

Thus, after the application of the contingency, the voltage angles are calculated based on the modified Thévenin equivalents, and in an iterative process, the Thévenin equivalents are re-calculated based on the calculated voltage angles, and re-calculated voltage angles are calculated based on the re-calculated Thévenin equivalents. The re-calculated voltage angles are compared with the calculated voltage angles, to provide a change in voltage angle, and subject to the convergence criterion, such when for example the change in voltage angle becomes lower than a threshold change in voltage angle, the power system is in a static mode, and an evaluation of the power system may be performed.

In another exemplary method, in 1f′, the power flow in the network 14 is evaluated.

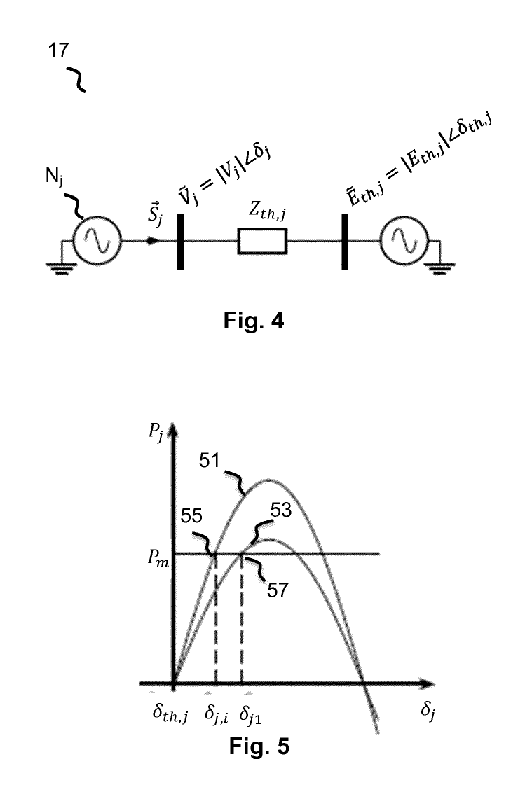

FIG. 4 shows a two-source Thévenin equivalent representation 17 of a power system 10 seen from a voltage controlled node Nⱼ. The two source Thévenin equivalent representation 17 comprises a voltage phasor \tilde{V}ⱼ and a Thévenin equivalent represented by the Thévenin voltage \tilde{E}_{th,j} and the Thévenin impedance Z_{th,j}, wherein the voltage phasor \tilde{V}ⱼ is the voltage phasor at the voltage controlled node Nⱼ and the Thévenin equivalent is representing the network as seen from the voltage controlled node Nⱼ.

The voltage phasor \tilde{V}ⱼ is given by a voltage magnitude |Vⱼ| and a voltage angle δⱼ determined at the voltage controlled node Nⱼ, i.e. \tilde{V}ⱼ=|Vⱼ|∠δⱼ.

The Thévenin equivalent comprises a Thévenin voltage \tilde{E}_{th,j} and a Thévenin impedance Z_{th,j}, wherein the Thévenin voltage is given by a Thévenin voltage magnitude |E_{th,j}| and a Thévenin voltage angle δ_{th,j} i.e. \tilde{E}_{th,j}=|E_{th,j}|∠δ_{th,j}. The Thévenin impedance Z_{th,j} is given by a Thévenin impedance magnitude |Z_{th,j}| and a Thévenin impedance angle δ_{th,j}, i.e. Z_{th,j}=|Z_{th,j}|∠δ_{th,j} or Z_{th,j}=R_{th,j}+iX_{th,j}.

The active power injection Pⱼ=Re{\vec{S}ⱼ} at the voltage controlled node Nⱼ is given by:

$${P}_{j} = \frac{{X}_{th , j} \vert {V}_{j} \vert \vert {E}_{th , j} \vert}{{R}_{th , j}^{2} + {X}_{th , j}^{2}} sin {δ}_{j} - \frac{{R}_{th , j} \vert {V}_{j} \vert \vert {E}_{th , j} \vert}{{R}_{th , j}^{2} + {X}_{th , j}^{2}} cos {δ}_{j} + \frac{{R}_{th , j} {\vert {V}_{j} \vert}^{2}}{{R}_{th , j}^{2} + {X}_{th , j}^{2}}$$

FIG. 5 shows the power injection Pⱼ as a function of a voltage angle δⱼ at a voltage controlled node Nⱼ, when the voltage magnitude |Vⱼ| and the Thévenin equivalent are constants, and the P−δ curve thus shows a relation between active power injection and voltage angle at a point of constant voltage and the system thus admits a steady state. Furthermore, a mechanical power Pₘ of a rotor shaft configured to a generator is shown.

A voltage angle δⱼ of a voltage controlled node Nⱼ may be determined when the network 14 is in steady state, i.e. when the power injection Pⱼ from the voltage controlled node Nⱼ is at least equal to the mechanical power Pₘ.

δ_{j,i} represents an initial voltage angle as measured in a pre-fault operational mode. Thus, the initial or pre-fault voltage angle may be described by the curve 51 (the electrical output of the node), and the point of operation for the j'th node of the power system, Nⱼ, in the pre-fault condition, or pre-contingency condition, is illustrated by the intersection 55, wherein, in the steady state mode, the mechanical power Pₘ equals the active power injection, Pⱼ. The post-fault, or post-contingency, condition, the point of operation δⱼ₁ may be derived from the change in Thévenin equivalent, thus the voltage angle δⱼ₁ may be calculated based on the modified Thévenin equivalents and the voltage angle may be described by the curve 53. The post-fault, or post-contingency, point of operation for the j′th voltage controlled node, is illustrated by the intersection 57, wherein, in the steady state mode, the mechanical power equals the active power injection.

δⱼ₀ may thus represent a calculated or measured voltage angle determined at the voltage controlled node Nⱼ before a contingency is applied to the network 14, and δⱼ₁ may represent a modified voltage angle determined at the voltage controlled node Nⱼ after the contingency is applied to the network 14.

An unstable condition may occur if the power injection Pⱼ at the voltage controlled node Nⱼ does not exceed the mechanical input power Pₘ. For example, the unstable condition may occur because of a broken transmission line grid or a broken generator.

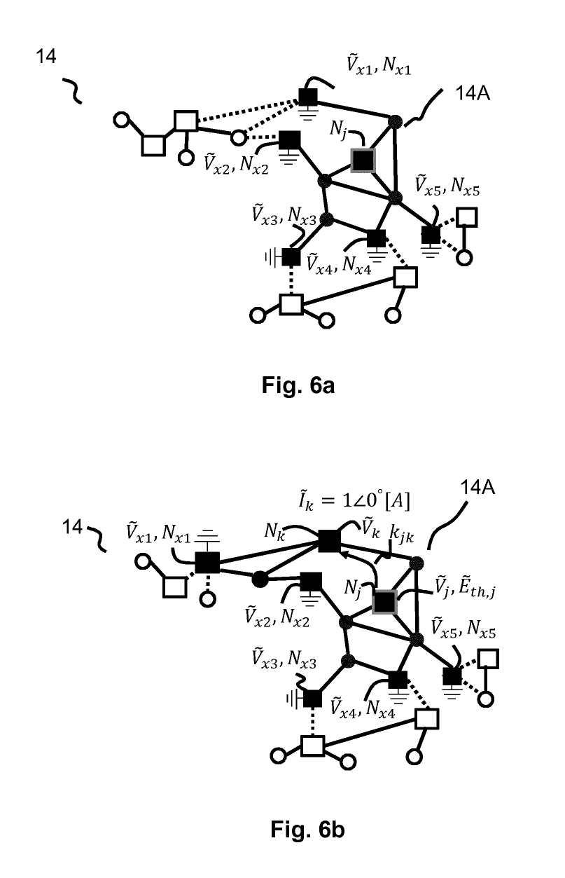

The network may be represented by a plurality of the voltage controlled nodes, a plurality of non-controlled nodes, or voltages at nodes without voltage control, interconnected via branches. For the present analysis, it has proven advantageous to pre-suppose that each voltage controlled node is primarily influenced by neighbouring voltage controlled nodes, such as by first degree neighbouring voltage controlled nodes, or second degree neighbouring voltage controlled nodes. Hereby, for the analysis, as seen in FIG. 6a, a secondary network 14A may be configured in the network 14 and forming part of the network 14, for each voltage controlled node.

It is an advantage of representing the network using a secondary network for each voltage controlled node in that the analysis may then be performed using parallel computing.

The secondary network 14A is represented by a voltage controlled node Nⱼ looking into a plurality of other voltage controlled nodes (N_{X1}-N_{X5})and multiple non-controlled nodes. Each voltage controlled node in the secondary network being illustrated by a solid black square and each non-controlled node in the secondary network being represented by a solid black circle. The multiple non-controlled nodes may for example be loads and may consume the power generated by the voltage controlled nodes (Nₓ, Nⱼ).

The voltage controlled nodes and the non-controlled nodes outside of the secondary network, and thus not forming part of the secondary network are illustrated by white squares and white circles, respectively.

FIG. 6a shows the secondary network 14A and in this particular example and for the purpose of determining the Thévenin equivalent of the network as seen from the Nⱼ node, the secondary network 14A is represented by a voltage controlled node Nⱼ, a plurality of short circuited voltage controlled nodes (N_{X1}-N_{X5}) and multiple non-controlled nodes.

FIG. 6b shows a secondary network 14A, and corresponding Thévenin equivalents and grid transformation coefficients.

An open-circuit is established at the voltage controlled node Nⱼ, and the Thévenin voltage \tilde{E}_{th,j} may be determined as seen from the voltage controlled node Nⱼ. The grid transformation coefficients may be determined from the network in that the secondary network 14A comprises another voltage controlled node Nₖ. A unit current is injected at the other voltage controlled node Nₖ while short circuiting all remaining voltage controlled nodes (Nₓ₁-Nₓ₅). With the configuration of the secondary network 14A, a grid transformation coefficient kⱼₖ may be determined as a relation between a voltage phasor \tilde{V}ⱼ determined at the voltage controlled node Nⱼ and at least a voltage phasor \tilde{V}ₖ determined at another voltage controlled node Nₖ.

Alternatively, the grid transformation coefficient may be defined as a relation between the Thévenin equivalent voltage \tilde{E}_{th,j} determined at the voltage controlled node Nⱼ and the voltage phasors determined at any other voltage controlled nodes.

As a further alternative, the grid transformation coefficient may be defined as a relation between the Thévenin equivalent voltage \tilde{E}_{th,j} calculated at the voltage controlled node Nⱼ and voltage phasors determined at neighbouring voltage controlled nodes.

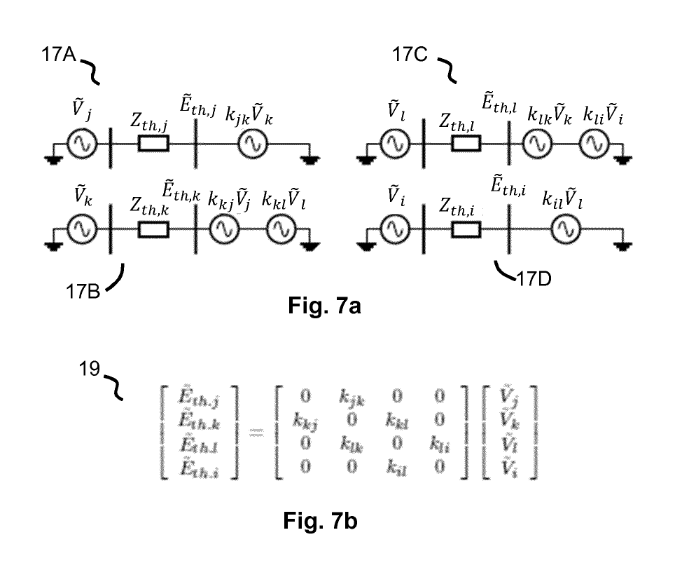

FIG. 7a shows a representation of the network having four voltage controlled nodes, each being expressed by coupled two-source Thévenin equivalents. The representation of the network 14 is based on a two-source equivalent (17A-17D), wherein the two-source equivalent comprises the determined Thévenin equivalent and a corresponding voltage phasor of a corresponding voltage controlled node.

A first representation 17A of the network 14 is seen from a voltage controlled node Nⱼ, having a Thévenin equivalent of the voltage controlled node Nⱼ and having at least one other voltage controlled node Nₖ with a voltage phasor \tilde{V}ₖ. The relation between a Thévenin voltage \tilde{E}_{th,j} and the voltage phasor \tilde{V}ₖ of the other voltage controlled node is represented by grid transformation coefficient kⱼₖ.

A second representation 17B of the network 14 is seen from a voltage controlled node Nₖ. Thévenin equivalent of the voltage controlled node Nₖ representing a secondary network 14A having at least two other voltage controlled nodes (Nⱼ,Nₗ), wherein a voltage controlled node Nⱼ, with a voltage phasor \tilde{V}ⱼ, and a voltage controlled node Nₗ, with a voltage phasor \tilde{V}ₗ, are each related to a Thévenin voltage \tilde{E}_{th,k} of the voltage controlled node Nₖ through grid transformation coefficients kₖⱼ and kₖₗ, respectively.

A third representation 17C of the network 14 is seen from a voltage controlled node Nₗ. Thévenin equivalent of the voltage controlled node Nₗ representing a secondary network 14A having at least two other voltage controlled nodes (Nₖ,Nᵢ), wherein a voltage controlled node Nₖ, with a voltage phasor \tilde{V}ₖ, and a voltage controlled node Nᵢ, with a voltage phasor \tilde{V}ᵢ, are each related to a Thévenin voltage \tilde{E}_{th,l} of the voltage controlled node Nₗ through grid transformation coefficients kₗₖ and kₗᵢ, respectively.

A fourth representation 17D of the network 14 is seen from a voltage controlled node Nᵢ, wherein Thévenin equivalent of the voltage controlled node Nᵢ represent a secondary network 14A having at least one other voltage controlled node Nₗ with a voltage phasor \tilde{V}ₗ. The relation between a Thévenin voltage \tilde{E}_{th,i} and the voltage phasor \tilde{V}ₗ of the other voltage controlled node Nₗ is represented by a grid transformation coefficient kᵢₗ.

FIG. 7b shows a grid transformation matrix 19 comprising the calculated Thévenin voltages (\tilde{E}_{th,j}, \tilde{E}_{th,k}, \tilde{E}_{th,l}, \tilde{E}_{th,i}) for each four voltage controlled nodes (Nⱼ, Nₖ, Nₗ, Nᵢ), one or more corresponding grid transformation coefficients and one or more corresponding voltage phasors (\tilde{V}ⱼ, \tilde{V}ₖ, \tilde{V}ₗ, \tilde{V}ᵢ)of the voltage controlled nodes (Nⱼ, Nₖ, Nₗ, Nᵢ).

It is an advantage of the grid transformation matrix 19 that it clearly indicates whether or not a direct coupling exists between two voltage controlled nodes in terms of a corresponding grid transformation coefficient.

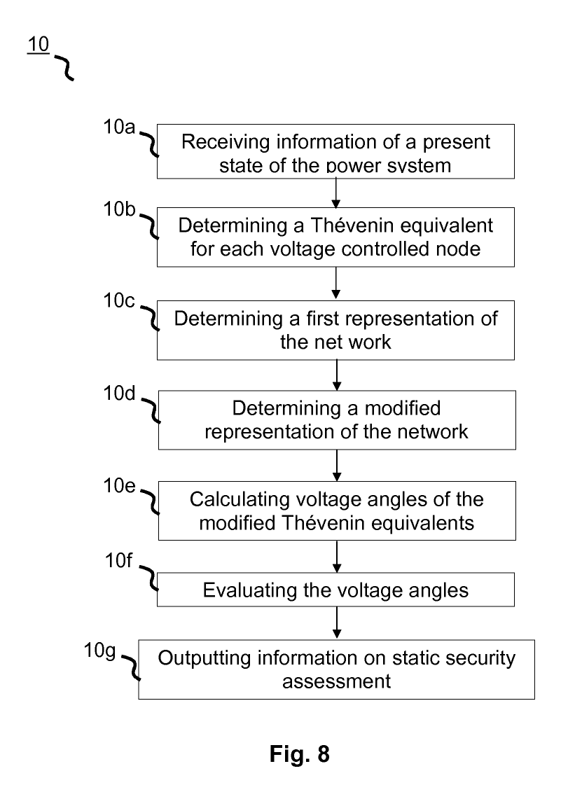

FIG. 8 is a flow chart of a method 10 for providing information on a real time static security assessment of a power system 10. The power system 10 having a plurality of generators 11 injecting power \vec{S}ⱼ into a network 14 having a plurality of nodes (15, 16) and a plurality of branches 12. The plurality of generators 11 are represented in the network 14 by a plurality of voltage controlled nodes 16.

In step 10a, information of a present state of the power system 10 is received, and in step 10b, a Thévenin equivalent for each voltage controlled node 16 is determined, wherein a Thévenin equivalent may be determined for each voltage controlled node 16 on basis of the determined present state of the power system 10.

In step 10c, a first representation of the network 14 based on the determined Thévenin equivalents is determined, and in step 10d, a modified representation of the network 14 is determined, wherein the modified representation is a representation of the network 14 having at least one contingency, wherein at least one Thévenin equivalent of at least one voltage controlled node 16 is modified due to the at least one contingency. The modified network representation is determined on the basis of the modified Thévenin equivalents.

In step 10e, voltage angles δⱼ₀ of the modified Thévenin equivalents are calculated, and in step 10f, the voltage angles δⱼ₀ are evaluated to determine whether the network 14 having at least one contingency is in steady state.

In step 10g, the method is configured to output information comprising evaluated voltage angles on static security assessment of the modified representation of the network, wherein the information comprises the evaluated voltage angles.

The information may be output to a second system configured to determine a remedial control action for a power system 10 having a plurality of generators 11 that are in an unstable or insecure state, especially to real-time determination of remedial control actions to be carried out.

Furthermore, the information may be output to a third system configured to assessing stability of a power system 10 having a plurality of generators 11, especially to real-time stability assessment of the power system 10. Additionally, the third system may also relate to a determination of stability boundary conditions for the power system 10, and a determination of the system 10 security margins.

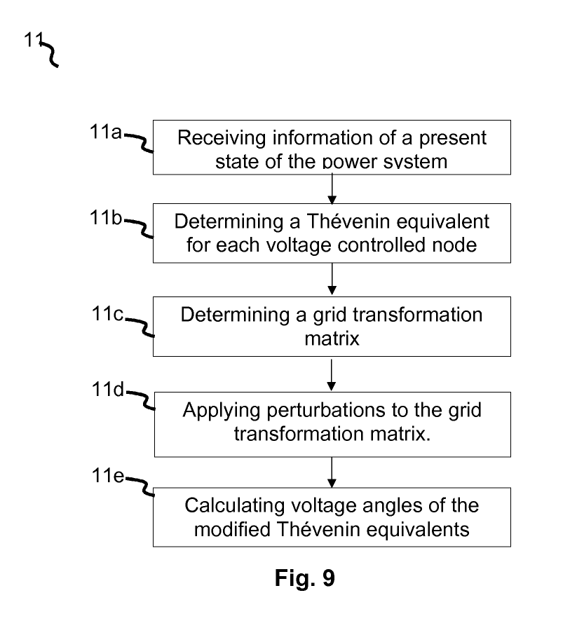

FIG. 9 is flow chart of a method 11 for conducting contingency analyses in static security assessment of a power system. The power system having a plurality of generators injecting power into a network having a plurality of nodes and a plurality of branches, the plurality of generators being represented in the network by a plurality voltage controlled nodes. The method comprises following steps:
11a) receiving information of a present state of the power system,
11b) determining a Thévenin equivalent for each voltage controlled node, such as a two source Thévenin equivalent, wherein the Thévenin voltages (Vₜₕ) and Thévenin impedances (Zₜₕ) are calculated for each voltage controlled node on basis of the determined present state of the power system,
11c) determining a grid transformation matrix based on the calculated Thévenin equivalents (Vₜₕ, Zₜₕ, and Iₜₕ), and wherein the grid transformation matrix comprises the calculated Thévenin equivalents for each voltage controlled node,
11d) applying perturbations to the grid transformation matrix and thereby modifying the Thévenin equivalents with at least one contingency,
11e) calculating voltage angles of the modified Thévenin equivalents on basis of the two source Thévenin equivalents for each predetermined selection of voltage controlled nodes, and wherein the Thévenin voltages (Vₜₕ) are updated with the calculated voltage angles, and new voltage angles are calculated on basis of the updated Thévenin voltages.

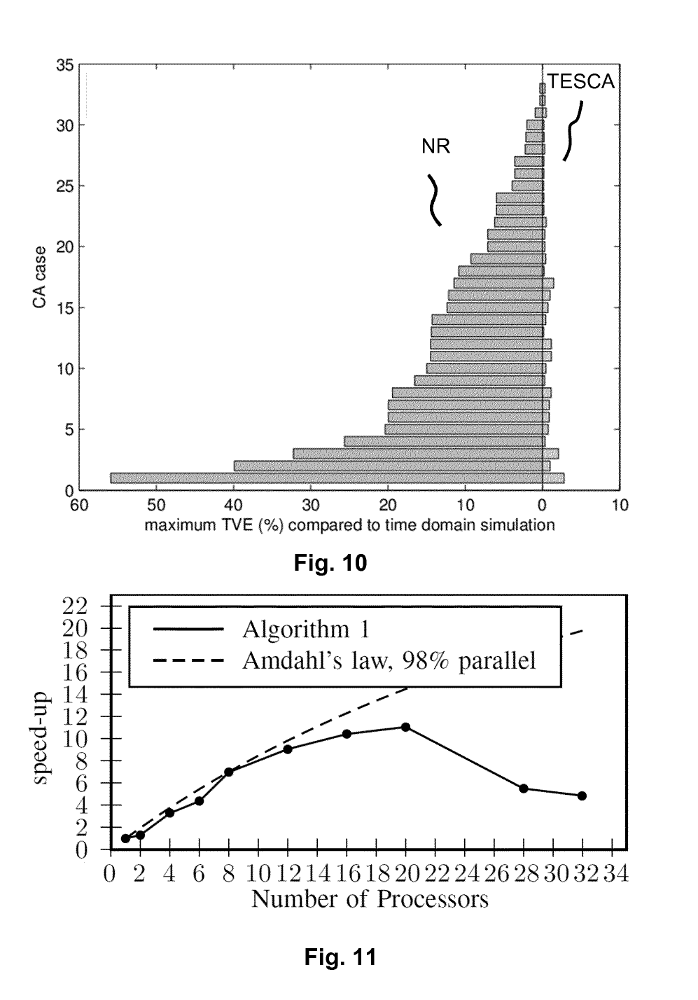

FIG. 10 shows a simulation result of a method according to the present invention and of Newton Raphson's power flow method (NR).

In this specific example, the method according to the present invention is denoted as Thévenin Equivalent based Static Contingency Assessment (TESCA).

The test power system used in this case was inspired by the Nordic32 test system and was implemented in a software tool, named Power System Simulator for Engineering (PSS/E). The power system consists of 46 nodes of which 20 are voltage controlled. Modifications were made to branch elements as to neglect resistive losses and generating units in order to represent them with identical dynamic characteristics.

A contingency analysis or assessment is conducted in PSS/E using the prior art method of time domain simulations. Typically, time domain simulations are too time consuming to perform in real-time, however, they are known to provided very precise results and therefore suitable as reference for further test methods.The cases studied reflect the total set of 33 individual N-1 cases related to loss of a single 400 kV line. Time response to every contingency was studied to determine an instant of steady-state at which a snapshot of nodal voltages could be taken. This snapshot would be used as a time domain reference for comparing with the Newton Raphson power flow method and the Thévenin Equivalent based Static Contingency Assessment, respectively.

A prior art Newton Raphson power flow method (NR) was conducted in PSS/E using the same modifications to the test power system as described above. The input scenario was identical to that used for time domain simulations except the selection of a slack-bus at which active power mismatches are balance as required in NR. NR converged in all 33 scenarios (i.e. the network converges towards a steady state in all 33 scenarios). The Newton Raphson power flow method typically evaluates the power provided to the system and whether the system is in a steady state.

A Thévenin Equivalent based Static Contingency Assessment (TESCA) according to the present disclosure is implemented in Matlab. Simulations are conducted on an input scenario composed of an admittance matrix and an initial set of nodal voltages and power injections. The input scenario is consistent with that used for time domain simulations to a precision of 10⁻⁵. The Thévenin impedances and the grid transformation matrix were modified according to the 33 contingencies, and post-contingency snapshots of steady state nodal voltages were obtained. It is an advantage of the Thévenin Equivalent based Static Contingency Assessment that also the rotor angle is included in the analysis, as compared with for example the Newton Raphson power flow method.

In order to compare the nodal voltages, determined by the Newton Raphson power flow method and the method using Thévenin Equivalent based Static Contingency Assessment, respectively, a common angular reference is required. A reference node is chosen as a solid reference between the datasets originating from the Newton Raphson power flow method and the method using Thévenin Equivalent based Static Contingency Assessment, respectively, and the time domain reference. All snapshots of post contingency nodal voltages are rotated so the voltage angle at the reference node is exactly identical in all data sets. Errors between results obtained by Newton Raphson power flow method and the method using Thévenin Equivalent based Static Contingency Assessment, respectively, i.e. the methods under test, and the time domain reference cases are stated in terms of a total vector error (TVE):

$$TVE = \frac{\vert {\tilde{V}}_{MUT} - {\breve{V}}_{TD} \vert}{\vert {\breve{V}}_{TD} \vert} \cdot 100 \%$$

, where \tilde{V}_{VMUT} refers to a voltage node determined by one of the methods under test and \tilde{V}_{TD} refers to a voltage node determined by the result in the time domain. TVE is determined for every single voltage phasor of a snapshot.

Choice of reference node impacts the distribution of TVEs over a snapshot as any error originating from the angle of the reference phasor will be transferred to the remaining TVEs of the test system. Therefore results of Newton Raphson power flow method and the method using Thévenin Equivalent based Static Contingency Assessment, respectively, are evaluated on basis of the single largest TVE in every post-contingency snapshot.

FIG. 10 shows contingency cases ordered according to descending error of Newton Raphson power flow method results together with the corresponding maximum error of the Thévenin Equivalent based Static Contingency Assessment (TESCA). The figure shows that the Thévenin Equivalent based Static Contingency Assessment (TESCA) reproduces the time domain results with significantly better precision than Newton Raphson power flow method (NR). Of the 33 cases studied all results obtained by the Thévenin Equivalent based Static Contingency Assessment (TESCA) are within 3.0% TVE and most are within 1.0% TVE.

Therefore, an advantage of the method according to the present invention is that calculations may be reproduced with high precision, such as within 1.0% to 3.0% TVE.

FIG. 11 shows simulation results of a further embodiment of the method according to the present invention. In the further embodiment, the determining of respective Thévenin equivalents for respective voltage controlled nodes includes sequentially factorization of an admittance matrix on all non-controlled nodes and parallelization of determining Thévenin equivalents for voltage controlled nodes in a number of processors.

By parallelizing the determining of Thévenin equivalents in a number of processors improves the speed at which the static security assessment of the power system may be performed or the speed at which the contingency assessment of the power system may be performed, however at the expense of an increased load of internal communication between the processors.

The test system used in this particular example includes 2602 branches and 1648 nodes of which 313 are with voltage control. The resulting grid transformation matrix is a 313 by 313 matrix with 56478 non-zero entries.

In FIG. 11, The Algorithm 1 curve represents the further embodiment taking into account the load of internal communication between the processors, and the Amdahl curve represents the further embodiment without taking into account the load of internal communication between the processors.

For the Amdahl curve, it is seen that the speed increases almost linearly with increased number of processors, until the load of the sequentially factorization of the admittance matrix starts to dominate.

For the Algorithm 1 curve, it is seen that the speed increases up to 12 processors at which point the increase of the internal communication between the processors starts to dominate the advantage of adding more processors.

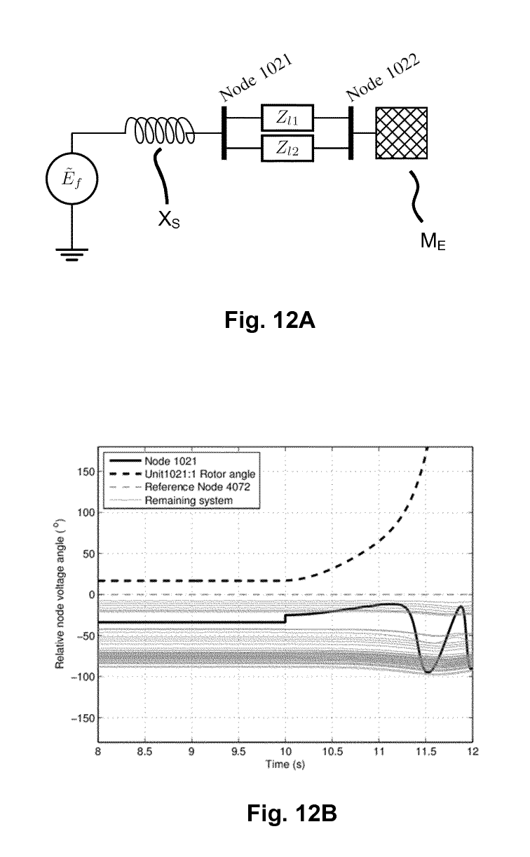

FIGS. 12A and 12B show the Nordic 32 test system and simulation results of a method according to the present invention, respectively, and where the result shows the development in voltage angle following tripping of a line between two busses.

In this specific example, the method according to the present invention is denoted as Thévenin Equivalent based Static Contingency Assessment (TESCA).

In this case, the Thévenin Equivalent based Static Contingency Assessment is applied to a test system, see FIG. 12A, for screening of Aperiodic Small-Signal Rotor Angle Stability (ASSRAS), and the applied contingency is limited to loss-of-line contingencies. The test power system used is a modification of the Nordic 32 Cigre test power system. The test power system is modified to make it prone to Aperiodic Small-Signal Rotor Angle instability by removing a generating unit from a first node, denoted as node 1021, and changing the exciter of a 200 MW unit at a second node, denoted as node 1022, to manually excite M_{E}. In Thévenin Equivalent based Static Contingency Assessment, a manually excited machine was modelled as an internal voltage \check{E}ⱼ of constant magnitude behind a synchronous reactance Xₛ.

Thévenin Equivalent based Static Contingency Assessment was used to identify contingencies causing aperiodic small signal instability in a case where the cause of Aperiodic Small-Signal Rotor Angle instability was due to loss of either of the lines connecting nodes 1021 and 1022. To verify the results of Thévenin Equivalent based Static Contingency Assessment, the time response of this event was simulated using PSS/E.

FIG. 12 shows the result for the voltage angles and the rotor angle for a machine, denoted as unit 1021:1. As seen in FIG. 12, at time equals to 10 seconds, one of the lines, connecting the generator at node 1021 with the remaining system, is tripped causing the rotor angle to increase. The voltage angle of the machine starts to oscillate when the rotor angle of the machine has increased to a certain level. In this specific example, the machine starts to be unstable when the rotor angle is approximately 100° (i.e. at time equals to 11.3 seconds).

Furthermore, FIG. 12 shows that the method is able to predict, by introducing a contingency into a power system that if the contingency is going to happen in real life an instable power system would be the result.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed as being a reference to the plural and vice versa.

A person skilled in the art will readily appreciate that various parameters disclosed in the description may be modified and that various embodiments disclosed and/or claimed may be combined without departing from the scope of the invention.

1. A method for conducting contingency analyses in static security assessment of a power system, the power system having a plurality of generators injecting power into a network having a plurality of nodes and a plurality of branches, the plurality of generators being represented in the network by a plurality of voltage controlled nodes, the method comprising:
receiving information of a present state of the power system,
determining a Thévenin equivalent for each voltage controlled node, wherein a Thévenin equivalent is determined for each voltage controlled node on the basis of the determined present state of the power system,
determining a representation of the network based on the determined Thévenin equivalents,
applying at least one contingency to the network,
determining a modified representation of the network, wherein the modified network representation is a representation of the network having at least one applied contingency, wherein at least one Thévenin equivalent of at least one voltage controlled node is modified due to the at least one applied contingency, the modified network representation being determined on the basis of the modified Thévenin equivalents,
calculating voltage angles of the modified Thévenin equivalents, and
evaluating the voltage angles to determine whether the network having at least one applied contingency admits a steady state.

2-17. (canceled)

18. The method according to claim 1, wherein the representation of the network is based on a two-source equivalent, wherein the two-source equivalent comprises the determined Thévenin equivalent and a voltage phasor of the voltage controlled node.

19. The method according to claim 1, wherein the method comprises evaluating whether the application of the contingency results in a stable network condition.

20. The method according to claim 1, wherein the at least one contingency is a topological change to the network.

21. The method according to claim 1, wherein the at least one contingency is a broken transmission line grid, a loss of a single transmission line, a loss of a generator, a damaged generator and/or any fault that provide a fault to the power system that may result in an unstable power system.

22. The method according to claim 1, wherein voltages at voltage controlled nodes and/or at non-controlled voltage nodes are compared against operational limits.

23. The method according to claim 1, wherein the calculation of the Thévenin equivalent for each voltage controlled node is performed assuming a constant active power injection and constant voltage magnitudes for each voltage controlled node.

24. The method according to claim 1, wherein a grid transformation matrix comprises calculated Thévenin voltages for each voltage controlled node, one or more corresponding grid transformation coefficients and one or more corresponding voltages of voltage controlled nodes and/or wherein a grid transformation coefficient is a relation between the Thévenin equivalent voltage at a voltage controlled node and voltage phasors at neighbouring voltage controlled nodes.

25. The method according to claim 22, wherein the determined Thévenin equivalents on which the first network representation is based corresponds to Thévenin equivalents on which the modified network representation is based in at least the part of the modified network representation corresponding to a part of the first network representation.

26. The method according to claim 1, wherein the step of determining a present state of the power system comprises obtaining synchronized Phasor Measurement Unit measurements from a plurality of nodes of the power system.

27. The method according to claim 1, wherein the Thévenin equivalents, the modified Thévenin equivalents and/or the voltage angles are determined in real-time.

28. The method according to claim 1, wherein the Thévenin equivalent comprises a Thévenin voltage and a Thévenin impedance, and wherein determined Thévenin voltages are re-calculated based on the calculated voltage angles of the modified Thévenin equivalents, and modified voltage angles are calculated on basis of the updated Thévenin voltages and wherein a change in voltage angle is evaluated.

29. The method according to claim 28, wherein evaluating the change in voltage angle is performed until a convergence criterion is satisfied.

30. A computer program comprising a program code configured to perform the method according to claim 1, when executed on a computer.

31. A computer readable medium having stored thereon a program code configured to perform the method according to claim 1, when executed on a computer.

32. A real time static security assessment system for conducting contingency analyses in a power system, the power system having a plurality of generators injecting power into a network having a plurality of nodes and a plurality of branches, the plurality of generators being represented in the network by a plurality of nodes of power injection, the system comprises:
a data processor configured to:
receive information of a present state of the power system,
determine a Thévenin equivalent for each voltage controlled node, wherein a Thévenin equivalent is determined for each voltage controlled node on the basis of the determined present state of the power system,
determine a representation of the network based on the determined Thévenin equivalents,
apply at least one contingency to the network,
determine a modified representation of the network, wherein the modified network representation is a representation of the network having at least one applied contingency, wherein at least one Thévenin equivalent of at least one voltage controlled node is modified due to the at least one contingency, the modified network representation being determined on the basis of the modified Thévenin equivalents,
calculating voltage angles of the modified Thévenin equivalents,
evaluating the voltage angles to determine whether the network having at least one applied contingency admits a steady state, and
an interface configured to output information on the static security assessment of the modified network representation of the network, wherein the information comprises the evaluated voltage angle.

33. A method of providing information on a real time static security assessment of a power system, the power system having a plurality of generators injecting power into a network having a plurality of nodes and a plurality of branches, the plurality of generators being represented in the network by a plurality of nodes of power injection, the method comprising:
receiving information of a present state of the power system, determining a two source Thévenin equivalent representation, where the representation includes the power system as seen from each voltage controlled node, wherein a Thévenin equivalent is determined for each voltage controlled node on basis of the determined present state of the power system, wherein the Thévenin equivalent comprises a Thévenin voltage and a Thévenin impedance,
determining a representation of the network based on the determined Thévenin equivalents,
applying at least one contingency to the network, determining a modified representation of the network representation, wherein the modified network representation of the network having at least one applied contingency, wherein at least one Thévenin equivalent of at least one voltage controlled node is modified due to the at least one contingency, the modified network representation being determined on the basis of the modified Thévenin equivalents,
calculating voltage angles of the modified Thévenin equivalents,
evaluating the voltage angle to determine whether the network having at least one applied contingency admits a steady state, and
outputting information on static security assessment of the modified representation of the network, wherein the information comprises the evaluated voltage angles.
